(19) United States
(12) Patent Application Publication
(10) Pub. No.: US 2018/0231276 A1
(43) Pub. Date: Aug. 16, 2018

(54) Pre-Conditioned Air System with Recirculating Evaporative Air Cooling

(71) Applicant: Verde GSE, Inc., Palmetto, FL (US)

(72) Inventors: Richard L. Hansen, Parrish, FL (US); Jason Waters, Parrish, FL (US); Kyta Insixiengmay, Pinellas Park, FL (US)

(73) Assignee: Verde GSE, Inc., Palmetto, FL (US)

(21) Appl. No.: 15/898,406

(22) Filed: Feb. 16, 2018

Related U.S. Application Data
(60) Provisional application No. 62/459,902, filed on Feb. 16, 2017.

(51) Int. Cl. F25B 1/00; B64D 13/06; B64F 1/305; H05K 7/20

(52) U.S. Cl. CPC F25B 1/00; B64D 13/06; B64F 1/305; H05K 7/20309; B64D 2013/0688; H05K 7/20145; F25B 2400/06; B64D 2013/0662; H05K 7/20327

(57) ABSTRACT

Technologies are described for a recirculating evaporative air conditioning system. A pre-cooling evaporator may be coupled to a pre-cooling compressor and a pre-cooling condenser by a first closed refrigerant loop. A post-cooling evaporator may be coupled to a post-cooling compressor and a post-cooling condenser by a second closed refrigerant loop. A blower can draw ambient air through the pre-cooling evaporator and then blow the air out through the post-cooling evaporator. A discharge plenum can collect the air blown out through the post-cooling evaporator. A recirculation duct can recirculate a portion of the air collected at the discharge plenum back into the pre-cooling evaporator, into the post-cooling evaporator, or into any ducts or plenums associated therewith. A discharge duct can conduct a portion of the air collected at the discharge plenum into an aircraft, electrical equipment, an aircraft ground power unit, a passenger bridge, or other such aircraft ground support systems.

### CROSS-REFERENCE TO RELATED APPLICATION

This application claims the benefit of U.S. provisional patent application No. 62/459,902, filed on Feb. 16, 2018, entitled “Pre-Conditioned Air (PCA) System that recirculates pressurized conditioned air from single or multiple systems evaporators/plenums to cool ambient air entering evaporators/plenums, heated airstreams produced by blowers/fans, heat produced from electric components and condensers,” which is expressly incorporated herein by reference in its entirety.

### SUMMARY

Technologies are described herein for a recirculating evaporative air conditioning system. A pre-cooling evaporator may be coupled to a pre-cooling compressor and a pre-cooling condenser by a first closed refrigerant loop. A post-cooling evaporator may be coupled to a post-cooling compressor and a post-cooling condenser by a second closed refrigerant loop. A blower can draw ambient air through the pre-cooling evaporator and then blow the air out through the post-cooling evaporator. A discharge plenum can collect the air blown out through the post-cooling evaporator. A recirculation duct may be configured to recirculate a portion of the air collected at the discharge plenum back into the pre-cooling evaporator, into the post-cooling evaporator, or into any ducts or plenums associated therewith. A discharge duct can conduct a portion of the air collected at the discharge plenum into an aircraft, electrical equipment, an aircraft ground power unit, a passenger bridge, or other such aircraft ground support systems.

It should be appreciated that the above-described subject matter may also be implemented as an apparatus, a system, an installation process, a manufacturing process, or as an article of manufacture. These and various other features will be apparent from a reading of the following Detailed Description and a review of the associated drawings.

This Summary is provided to introduce a selection of concepts in a simplified form that are further described below in the Detailed Description. This Summary is not intended to identify key features or essential features of the claimed subject matter, nor is it intended that this Summary be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a system diagram illustrating a recirculating pre-conditioned air unit according to one or more embodiments presented herein;

FIG. 2 is a side view of a recirculated air cooled condenser according to one or more embodiments presented herein;

FIG. 3 is a from view of a recirculated air cooled condenser according to one or more embodiments presented herein;

FIG. 4 is a system diagram illustrating a recirculating pre-conditioned air unit supporting multiple an electrical enclosures according to one or more embodiments presented herein; and

FIG. 5 is a block flow diagram depicting a method for recirculating pre-conditioned air in aircraft ground support equipment according to one or more embodiments presented herein.

### DETAILED DESCRIPTION

The following description is directed to technologies for recirculating air conditioning systems. A pre-conditioned air (PCA) unit can provide pressurized, reclaimed, and recirculated conditioned air back into the unit. The recirculated air may be delivered into a pre-cooler or between a pre-cooler and a post-cooler stage. Recirculation can improve the cooling and drying of air supplied by the PCA to an aircraft, buildings, or auxiliary facilities such as passenger boarding bridges and electrical enclosures. The reclaimed and recirculated air may be collected from evaporators and/or discharge plenums and cycled back into the conditioning system to amplify the drying and cooler capacity of the pre-conditioned air unit.

In the following detailed description, references are made to the accompanying drawings that form a part hereof, and which are shown by way of illustration specific embodiments or examples. Referring now to the drawings, in which like numerals represent like, but not necessarily identical, elements through the several figures, aspects of head-mounted personal privacy solutions will be presented.

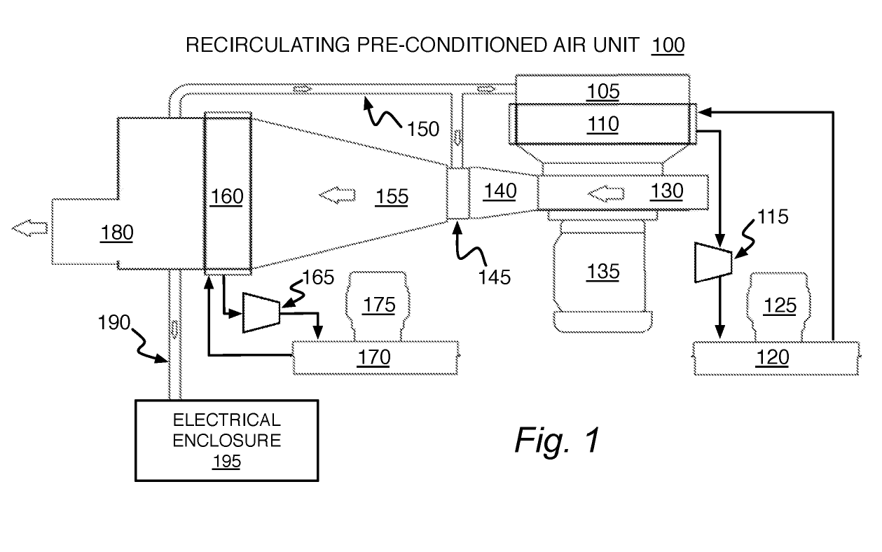

Turning first to FIG. 1, a system diagram illustrates a recirculating pre-conditioned air unit 100 according to one or more embodiments of the technology presented herein. The recirculating pre-conditioned air unit 100 may comprise an ambient intake plenum 105 for directing air into a pre-cooling evaporator 110. The pre-cooling evaporator 110 maybe coupled to a pre-cooling compressor 115 and a pre-cooling condenser 120. Generally, the pre-cooling evaporator 110, the pre-cooling compressor 115, and the pre-cooling condenser 120 are coupled by a closed refrigerant loop. The pre-cooling condenser 120 may comprise a fan operated by a pre-cooling condenser fan motor 125.

A blower 130 may comprise a blower motor 135. The blower 130 can draw ambient air through the pre-cooling evaporator 110 and force that air out through a post-blower nozzle 140, a post-blower coupling 145, and a post-blower plenum 155 through a post-cooling evaporator 160. The post-blower nozzle 140, post-blower coupling 145, and post-blower plenum 155 make up a plenum or duct for coupling pre-cooleded air from the pre-cooling evaporator 110 to the post-cooling evaporator 160. It should be appreciated that these elements (the post-blower nozzle 140, the post-blower coupling 145, and the post-blower plenum 155) may comprise fewer or additional plenum or duct elements without departing from the spirit of the technology disclosed herein.

The post-cooling evaporator 160 may be coupled to a post-cooling compressor 165 and a post-cooling condenser 170. Generally, the post-cooling evaporator 160, the post-cooling compressor 165, and the post-cooling condenser 170 are coupled by a closed refrigerant loop. The post-cooling condenser 170 may comprise a fan operated by a post-cooling condenser fan motor 175. Air forced through the post-cooling evaporator 160 may be conducted into a discharge plenum 180.

A portion of the air from the discharge plenum 180 may be delivered to aircraft and associated structures to support pre-cooling. A portion of the air from the discharge plenum 180 may be delivered as recirculated air 150 into the ambient intake plenum 105 of the recirculating pre-conditioned air unit 100. A portion of the air from the discharge plenum 180 may be delivered as recirculated air 190 to an electrical enclosure 195. Removal of a portion of the air from the discharge plenum 180 as recirculated air 150 and/or recirculated air 190 can serve as a relief to the discharge plenum 180 during high-pressure operations.

The portion of the air from the discharge plenum 180 delivered as recirculated air 150 into the ambient intake plenum 105 of the recirculating pre-conditioned air unit 100 may alternatively be delivered into the pre-cooling evaporator 110, the blower 130, the post-cooling evaporator 160, or any duct structures coupling to or between the ambient intake plenum 105, the pre-cooling evaporator 110, the blower 130, or the post-cooling evaporator 160.

The recirculated air 150 fed back into the pre-cooling evaporator 110 may be conducted via a recirculation duct. The recirculation duct may comprise a hose, a flexible duct, a rigid duct, a plenum, or any combination thereof. Recirculated air 150 within the recirculation duct may be modulated with a control damper or control valve. Alternatively, recirculated air 150 within the recirculation duct may be unmodulated. The recirculation duct may comprise a geometry or restriction structure sized to support the desired airflow. Alternatively, the recirculation duct may comprise no restriction and instead support a relatively unrestricted airflow.

The recirculated air 150 may be delivered into the ambient intake plenum 105 where it may be directed into the pre-cooling evaporator 110. Alternatively, the recirculated air 150 may be delivered directly into the pre-cooling evaporator 110. The recirculated air 150 may support supplemental or enhanced cooling of ambient air entering into the pre-cooling evaporator 110.

Instead of, or in addition to, delivering the recirculated air 150 back into the pre-cooling evaporator 110, the recirculated air 150 may be delivered into the post-cooling evaporator 160. For example, the recirculated air 150 may be directed into the post-blower nozzle 140, the post-blower coupling 145, the post-blower plenum 155, or some other duct or plenum serving to conduct pre-cooled air from the pre-cooling evaporator 110 to the post-cooling evaporator 160.

A portion of the air from the discharge plenum 180 may be delivered to aircraft and associated structures to support pre-cooling. For example, the recirculating pre-conditioned air unit 100 may be mounted on the ground or attached to passenger boarding bridges for convenient access to aircraft. A mobile recirculating pre-conditioned air unit 100 may be trailer mounted or mounted on a truck bed. The mobile embodiment can supply conditioned air to aircraft remotely located from airport gates or in military applications

The recirculating pre-conditioned air unit 100 may significantly improving cooling for aircraft, and associated structures, while on the ground for servicing. The cooling can support passenger comfort operations, military aircraft cooling, avionics cooling, cooling electrical enclosures 195 associated with controlling the recirculating pre-conditioned air unit 100, cooling other electrical enclosures 195, cooling other structures associated with the aircraft, or any combination thereof.

Pre-cooling and recirculation associated with the recirculating pre-conditioned air unit 100 may substantially reduce the moisture content of the air finally delivered from the post-cooling evaporator 160 into the discharge plenum 180.

Pre-cooling and recirculation associated with the recirculating pre-conditioned air unit 100 can substantially reduce the likelihood of the freeze-up within the cooling system. Accordingly, the need for system shut-downs or defrost cycles may be significantly reduced thereby increasing overall cooling system efficiency. For example, a refrigerant loop may normally operate near the 425-450 psi range and indicate a system shutdown if head pressure approaches 600 psi. Such shutdowns may be reduced or avoided altogether due to pre-cooling and recirculation associated with the recirculating pre-conditioned air unit 100.

Pre-cooling and recirculation associated with the recirculating pre-conditioned air unit 100 can substantially reduce the humidity of the air delivered from the discharge plenum 180. Drier air may be increasingly important for cooling system with sensitive electronics and avionics. One example of a modern aircraft can only have 18 grains of moisture per pound of dry air delivered to it. The recirculating pre-conditioned air unit 100 can deliver significantly drier air, which can extend the lifetime and reliability of the electronic and avionic systems being cooled.

The recirculating pre-conditioned air unit 100 may comprise single-circuit and multi-circuit vapor compression systems and/or chiller systems. The recirculating pre-conditioned air unit 100 may comprise a single pre-cooling evaporator 110 or multiple pre-cooling evaporators 110 operating in either series or parallel configurations. The recirculating pre-conditioned air unit 100 may comprise a single post-cooling evaporator 160 or multiple post-cooling evaporators 160 operating in either series or parallel configurations.

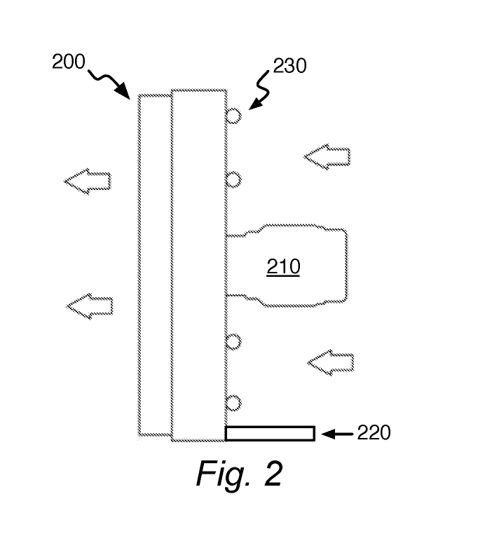

FIG. 2 is a side view of a recirculated air cooled condenser 200 according to one or more embodiments of the technology presented herein. The cooled condenser 200 may be cooled by recirculated air 150 delivered via a recirculated air inlet 220. The cooled condenser 200 may be a pre-cooling condenser 120, a post-cooling condenser 170, or another example of such a condenser. The cooled condenser 200 can cool and dry air blown through the cooled condenser 200.

Recirculated air 150 that is pre-cooled, such as a portion of the air from the discharge plenum 180, may be delivered into the recirculated air inlet 220. The recirculated air 150 may be cooler and drier. Prior to entering the cooled condenser 200, the air to be cooled can be mixed with the recirculated air 150, which can supplement cooling of the air being cooled.

Air being cooled may be blown through the cooled condenser 200 by a fan (not visible in this side view). A condenser fan motor 210 may be used to operate the fan. The air being cooled may be drawn around and across refrigerant tubing 230. The refrigerant tubing 230 may comprise tubes, pipes, fins, or plates. The refrigerant tubing 230 may conduct, or be thermally coupled to, a refrigerant contained within a closed compressor-evaporator-condenser loop.

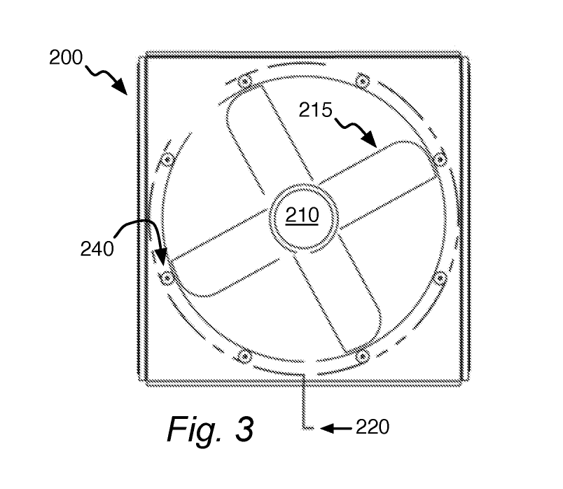

FIG. 3 is a front view of a recirculated air cooled condenser 200 according to one or more embodiments of the technology presented herein. Air being cooled may be blown through the cooled condenser 200 by a condenser fan 215 operated by the condenser fan motor 210.

Recirculated air 150 that is pre-cooled, such as a portion of the air from the discharge plenum 180, may be delivered into the recirculated air inlet 220. The cooled condenser 200 may be cooled by the recirculated air 150 to increase heat rejection. From the recirculated air inlet 220, the recirculated air 150 may be directed through the nozzles 240 to inject a cooler airstream through the condenser allowing for more efficient operation.

Reducing temperature of the cooled condenser 200 using the recirculated air 150 may be particularly useful as ambient temperature goes up in very hot environments. In such elevated heats, the condenser may work harder, which increases refrigerant pressure. Injecting the recirculated air 150 through the nozzles 240 can assist to cool the refrigerant tubing 230 reducing the load upon, or cycle time, of the condenser fan motor 210. Injecting the recirculated air 150 through the nozzles 240 can also reduce refrigerant pressure.

While the illustrated embodiment shows eight nozzles 240 distributed circularly around the cooled condenser 200, any other quantity of nozzles 240 in any other geometry or distribution may be used by other embodiments without departing from the scope or spirit of the technology presented herein.

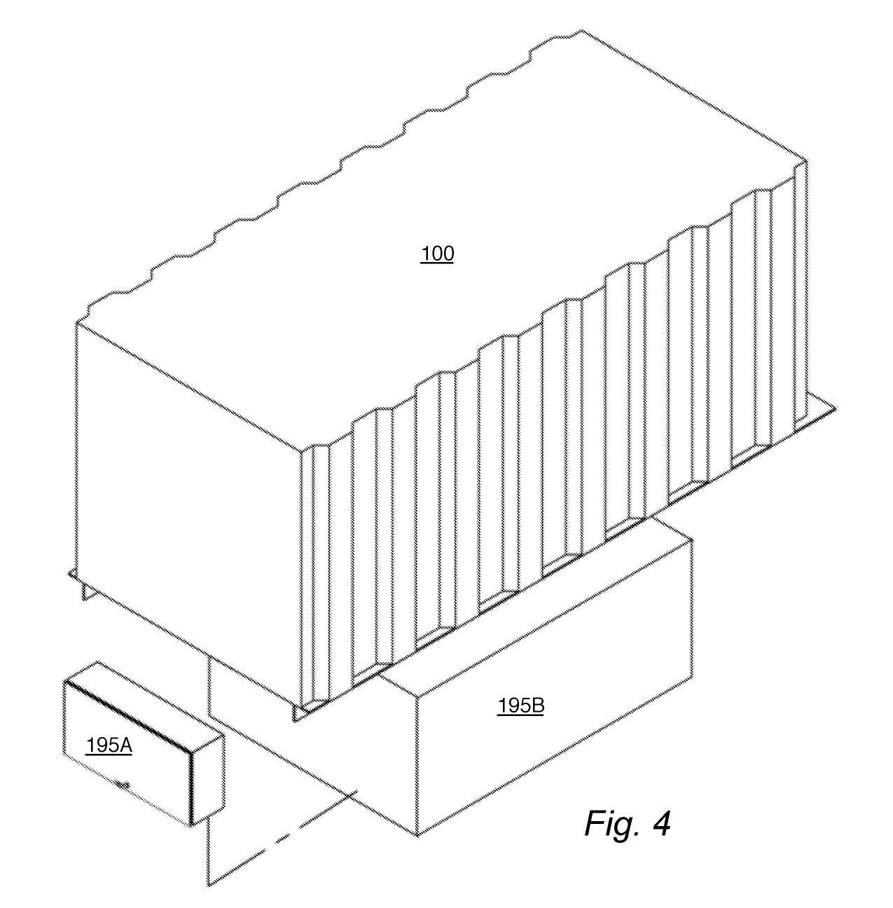

FIG. 4 is a system diagram illustrates a recirculating pre-conditioned air unit 100 supporting multiple an electrical enclosures 195 according to one or more embodiments of the technology presented herein. A first example electrical enclosure 195A may house electrical components and/or electronics associated with controlling the recirculating pre-conditioned air unit 100. A second example electrical enclosure 195B may house electrical components and/or electronics otherwise associated with the aircraft or ground support equipment. The first example electrical enclosure 195A and the second example electrical enclosure 195B may be collectively, or generally, be referred to as electrical enclosures 195. An example electrical enclosure 195 may support a power converter or ground power unit (GPU), which can serve as the power supply for the aircraft while it is on the ground.

A portion of the air from the discharge plenum 180 may be delivered as recirculated air 190 to an electrical enclosure 195. The recirculated air 190 delivered to one or more electrical enclosures 195 may be cooled and dried by the recirculating pre-conditioned air unit 100. A duct or hose may be connected to a plenum or evaporator associated with the recirculating pre-conditioned air unit 100 to conduct the recirculated air 190. Flow of the recirculated air 190 through the duct or hose can be modulated with a damper or control valve by measuring the cooled air temperature entering the electrical enclosure 195. Alternatively, flow of the recirculated air 190 may be unmodulated. Alternatively, a mechanicalrestriction within the duct or hose may be appropriately sized to regulate flow of the recirculated air 190. However delivery for the recirculated air 190 is controlled, temperatures below the electronic component temperature ratings may be maintained.

A return duct connected to the electrical enclosure 195 can return air from the electrical enclosure 195 to the ambient intake plenum 105 or into the pre-cooling evaporator 110. Cycling of the return air from the electrical enclosure 195 may be particularly useful when the return air has a lower temperature and/or lower humidity than ambient air.

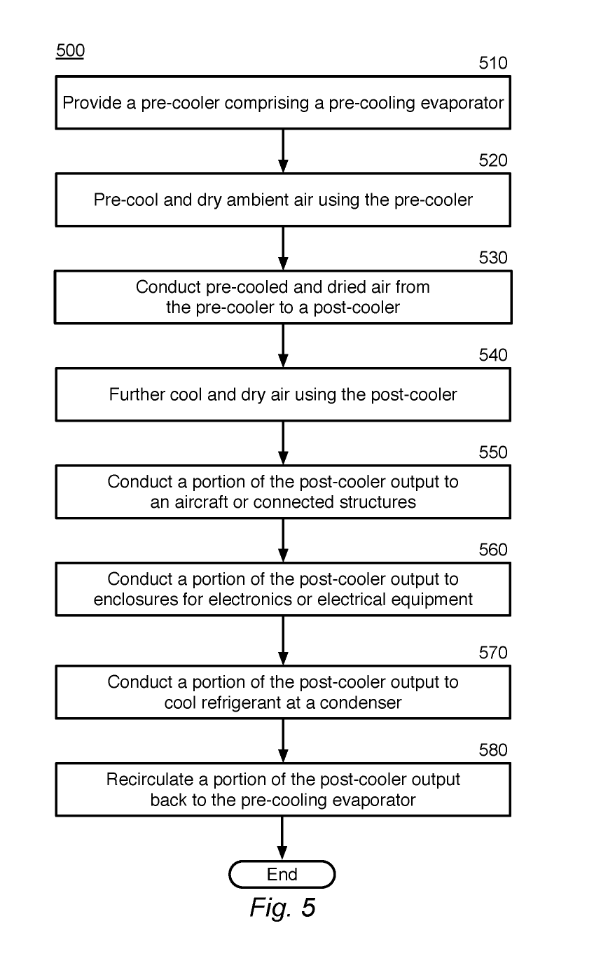

FIG. 5 is a block flow diagram depicting a method 500 for recirculating pre-conditioned air in aircraft ground support equipment in accordance with one or more embodiments presented herein. According to methods and blocks described in the embodiments presented herein, and, in alternative embodiments, certain blocks can be performed in a different order, in parallel with one another, omitted entirely, and/or combined between different example methods, and/or certain additional blocks can be performed, without departing from the scope and spirit of the invention. Accordingly, such alternative embodiments are included in the invention described herein.

In block 510, a pre-cooler may be provided. The pre-cooler may comprise a pre-cooling evaporator 110, a pre-cooling compressor 115, and a pre-cooling condenser 120. The pre-cooling evaporator 110, the pre-cooling compressor 115, and the pre-cooling condenser 120 may be coupled by a closed refrigerant loop. The pre-cooler may be associated with an ambient intake plenum 105 for directing air into the pre-cooling evaporator 110.

In block 520, ambient air may be pre-cooled and significantly dried using the pre-cooler.

In block 530, the pre-cooled and dried air from the pre-cooler may be conducted to a post-cooler. A blower 130 can draw ambient air through the pre-cooler and direct the air to the post-cooler. For example, the blower 130 can force the air out through a post-blower nozzle 140, a post-blower coupling 145, and a post-blower plenum 155 through to the post-cooler. The post-cooler may comprise a post-cooling evaporator 160, a post-cooling compressor 165, and a post-cooling condenser 170. Generally, the post-cooling evaporator 160, the post-cooling compressor 165, and the post-cooling condenser 170 are coupled together by a closed refrigerant loop.

In block 540, the air being conditioned may be further cooled and dried by the post-cooler.

In block 550, a portion of the air from the post-cooler may be delivered to an aircraft and/or associated structures to support pre-cooling. The recirculating pre-conditioned air unit 100 can significantly improving cooling for aircraft, and associated structures, while the aircraft is on the ground for servicing. For example, air from a discharge plenum 180 of a recirculating pre-conditioned air unit 100 can be piped or ducted into the aircraft or associated structures. The recirculating pre-conditioned air unit 100 may be mounted on the ground or attached to passenger boarding bridges for convenient access to aircraft. The cooling can support passenger comfort operations, military aircraft cooling, avionics cooling, cooling other structures associated with the aircraft, or any combination thereof.

In block 560, a portion of the post-cooler output may be conducted to electrical enclosures 195 for maintaining proper operating temperatures for electronics or electrical equipment. For example, a portion of the air from the discharge plenum 180 may be delivered as recirculated air 190 to an electrical enclosure 195. The recirculated air 190 delivered to one or more electrical enclosures 195 may be cooled and dried by the recirculating pre-conditioned air unit 100. A duct or hose may be connected to a plenum or evaporator associated with the recirculating pre-conditioned air unit 100 to conduct the recirculated air 190 to one or more electrical enclosures 195. The recirculating pre-conditioned air unit 100 can deliver significantly drier air, which can extend the lifetime and reliability of the electronic and avionic systems being cooled.

In block 570, a portion of the post-cooler output may be conducted to a condenser to cool refrigerant at the condenser. For example, a cooled condenser 200 may be cooled by recirculated air 150 conducted to a recirculated air inlet 220 associated with the cooled condenser 200. The recirculated air 150 may be directed from a discharge plenum 180 associated with a recirculating pre-conditioned air unit 100. The recirculated air 150 may be cooler and drier than the air being cooled at the condenser. Prior to entering the cooled condenser 200, the air to be cooled can be mixed with the recirculated air 150, which can supplement cooling and support efficient operation of the cooled condenser 200 and associated refrigerant loop.

In block 580, a portion of the post-cooler output may be recirculated back to the pre-cooling evaporator. For example, a portion of conditioned air from the discharge plenum 180 associated with a recirculating pre-conditioned air unit 100 may be delivered as recirculated air 150 into the ambient intake plenum 105 of the recirculating pre-conditioned air unit 100. The recirculated air 150 fed back into the ambient intake plenum 105 may be conducted via a recirculation duct. The recirculated air 150 may be ducted into the ambient intake plenum, the pre-cooling evaporator 110, the blower 130, the post-cooling evaporator 160, or any duct structures coupling to or between the ambient intake plenum 105, the pre-cooling evaporator 110, the blower 130, or the post-cooling evaporator 160. Recirculation of the conditioned air can significantly improve efficiency and efficacy of the recirculating pre-conditioned air unit 100 as presented herein.

Based on the foregoing, it should be appreciated that technologies for recirculating air conditioning systems in aircraft ground support equipment are presented herein. Although the subject matter presented herein has been described in specific language related to structural features or methodological acts, it is to be understood that the invention defined in the appended claims is not necessarily limited to the specific features or acts described herein. Rather, the specific features and acts are disclosed as example forms of implementation.

The subject matter described above is provided by way of illustration only and should not be construed as limiting. Various modifications and changes may be made to the subject matter described herein without following the example embodiments and applications illustrated and described, and without departing from the true spirit and scope of the present invention, which is set forth in the following claims.

What is claimed is:

1. A recirculating evaporative air conditioning system comprising:
a pre-cooling evaporator coupled to a pre-cooling compressor and a pre-cooling condenser by a first closed refrigerant loop;
a post-cooling evaporator coupled to a post-cooling compressor and a post-cooling condenser by a second closed refrigerant loop;
a blower configured to draw ambient air through the pre-cooling evaporator and blow the air out through the post-cooling evaporator;
a discharge plenum configured to collect the air blown out through the post-cooling evaporator;
a recirculation duct configured to recirculate a portion of the air collected at the discharge plenum back into the pre-cooling evaporator; and
a discharge duct configured to conduct a portion of the air collected at the discharge plenum into an aircraft ground support application.

2. The recirculating evaporative air conditioning system of claim 1, wherein the aircraft ground support application comprises a commercial aircraft cabin.

3. The recirculating evaporative air conditioning system of claim 1, wherein the aircraft ground support application comprises a military aircraft.

4. The recirculating evaporative air conditioning system of claim 1, wherein the aircraft ground support application comprises an avionics subsystem.

5. The recirculating evaporative air conditioning system of claim 1, wherein the aircraft ground support application comprises an electrical enclosure.

6. The recirculating evaporative air conditioning system of claim 1, wherein the aircraft ground support application comprises a passenger bridge associated with an aircraft.

7. The recirculating evaporative air conditioning system of claim 1, wherein the recirculating evaporative air conditioning system is operable to substantially reduce the humidity of the air collected at the discharge plenum.

8. The recirculating evaporative air conditioning system of claim 1, further comprising a duct configured to conduct a portion of the air collected at the discharge plenum into the pre-cooling condenser to cool a refrigerant associated with the first closed refrigerant loop.

9. The recirculating evaporative air conditioning system of claim 1, further comprising a duct configured to conduct a portion of the air collected at the discharge plenum into the post-cooling condenser to cool a refrigerant associated with the second closed refrigerant loop.

10. A recirculating evaporative air conditioning system comprising:
a pre-cooling evaporator coupled to a pre-cooling compressor and a pre-cooling condenser by a first closed refrigerant loop;
a post-cooling evaporator coupled to a post-cooling compressor and a post-cooling condenser by a second closed refrigerant loop;
a blower configured to draw ambient air through the pre-cooling evaporator and blow the air out through the post-cooling evaporator;
a discharge plenum configured to collect the air blown out through the post-cooling evaporator;
a recirculation duct configured to recirculate a portion of the air collected at the discharge plenum back into the post-cooling evaporator; and
a discharge duct configured to conduct a portion of the air collected at the discharge plenum into an aircraft ground support application.

11. The recirculating evaporative air conditioning system of claim 10, wherein the aircraft ground support application comprises a passenger cabin and a passenger bridge, both associated with a commercial aircraft.

12. The recirculating evaporative air conditioning system of claim 10, wherein the aircraft ground support application comprises a military aircraft.

13. The recirculating evaporative air conditioning system of claim 10, wherein the aircraft ground support application comprises an electrical cabinet associated with the recirculating evaporative air conditioning system.

14. The recirculating evaporative air conditioning system of claim 10, wherein the recirculating evaporative air conditioning system is operable to substantially reduce the humidity of the air collected at the discharge plenum.

15. The recirculating evaporative air conditioning system of claim 10, further comprising a duct configured to conduct a portion of the air collected at the discharge plenum into the pre-cooling condenser to cool a refrigerant associated with the first closed refrigerant loop.

16. The recirculating evaporative air conditioning system of claim 10, further comprising a duct configured to conduct a portion of the air collected at the discharge plenum into the post-cooling condenser to cool a refrigerant associated with the second closed refrigerant loop.

17. A method for recirculating pre-conditioned air within an aircraft ground support air-cooling system comprising the steps of:
providing a pre-cooling evaporator coupled to a pre-cooling compressor and a pre-cooling condenser by a first closed refrigerant loop;
providing a post-cooling evaporator coupled to a post-cooling compressor and a post-cooling condenser by a second closed refrigerant loop;
drawing ambient air through the pre-cooling evaporator, using a blower;
blowing the air drawn through the pre-cooling evaporator into the post-cooling evaporator, using the blower;
collecting the air blown through the post-cooling evaporator into a discharge plenum;
recirculating a first portion of the air collected at the discharge plenum back into the pre-cooling evaporator; and
conducting a second portion of the air collected at the discharge plenum into an aircraft ground support application.

18. The method of claim 17, wherein the aircraft ground support application comprises one of a commercial aircraft cabin, a military aircraft, an avionics subsystem, an electrical enclosure, a passenger bridge, and a ground power unit.

19. The method of claim 17, wherein the recirculating evaporative air conditioning system is operable to substantially reduce the humidity of the air collected at the discharge plenum.

20. The method of claim 17, further comprising a duct configured to conduct a third portion of the air collected at the discharge plenum into the pre-cooling condenser or into the post-cooling condenser.
